(19) United States
(12) Patent Application Publication
(10) Pub. No.: US 2024/0178268 A1
(43) Pub. Date: May 30, 2024

(54) CAPACITOR STRUCTURE

(71) Applicant: Powerchip Semiconductor Manufacturing Corporation, Hsinchu (TW)

(72) Inventors: Wei-Yu Lin, Hsinchu City (TW); Chuan-Chieh Lin, Hsinchu City (TW)

(73) Assignee: Powerchip Semiconductor Manufacturing Corporation, Hsinchu (TW)

(21) Appl. No.: 18/153,375

(22) Filed: Jan. 12, 2023

(30) Foreign Application Priority Data
Nov. 28, 2022 (TW) 111145420

(51) Int. Cl. H01L 23/522; H01G 4/08; H01G 4/232

(52) U.S. Cl. CPC H01L 28/75; H01G 4/08; H01G 4/232; H01L 23/5223

(57) ABSTRACT

A capacitor structure including a substrate, a capacitor, a second dielectric layer, a first conductive layer, and a second conductive layer is provided. The capacitor includes first electrode layers, at least one second electrode layer, and a first dielectric layer. The first electrode layers and the at least one second electrode layer are alternately disposed on the substrate. The first dielectric layer is disposed between the first electrode layer and the second electrode layer. The second dielectric layer has first openings and at least one second opening. The first openings expose the first electrode layers. The second opening exposes the second electrode layer. The first conductive layer is electrically connected to the first electrode layers. The first conductive layer is a single conductive layer disposed on the second dielectric layer and extending into the first openings. The second conductive layer is electrically connected to the second electrode layer.

### CROSS-REFERENCE TO RELATED APPLICATION

This application claims the priority benefit of Taiwan application serial no. 111145420, filed on Nov. 28, 2022. The entirety of the above-mentioned patent application is hereby incorporated by reference herein and made a part of this specification.

### BACKGROUND

### Technical Field

The invention relates to a passive device structure, and particularly relates to a capacitor structure.

### Description of Related Art

The capacitor is a passive device widely used in electronic products. Currently, the capacitance value of the capacitor structure is often increased by alternately stacking the first electrode layers and the second electrode layers, wherein the first electrode layers are electrically connected to each other, and the second electrode layers are electrically connected to each other connect. However, in the above capacitor structure, the interconnection structure for electrically connecting the first electrode layers to each other and the interconnection structure for electrically connecting the second electrode layers to each other have high process complexity and high manufacturing cost.

### SUMMARY

The invention provides a capacitor structure, which can effectively reduce the process complexity and the manufacturing cost.

The invention provides a capacitor structure, which includes a substrate, a capacitor, a second dielectric layer, a first conductive layer, and a second conductive layer. The capacitor includes first electrode layers, at least one second electrode layer, and a first dielectric layer. The first electrode layers and at least one second electrode layer are alternately disposed on the substrate. The first dielectric layer is disposed between one of the first electrode layers and the at least one second electrode layer. The second dielectric layer is disposed on the first electrode layers and the at least one second electrode layer and has first openings and at least one second opening. The first openings expose the first electrode layers. The at least one second opening exposes the at least one second electrode layer. The first conductive layer is electrically connected to the first electrode layers. The first conductive layer is a single conductive layer disposed on the second dielectric layer and extending into the first openings. The second conductive layer is electrically connected to the at least one second electrode layer. The second conductive layer is disposed on the second dielectric layer and in the at least one second opening.

According to an embodiment of the invention, in the capacitor structure, the first conductive layer may extend into all the first openings.

According to an embodiment of the invention, in the capacitor structure, the first conductive layer may include a conductive line portion and contact portions. The contact portions are connected to the conductive line portion. Each of the contact portions may be disposed in the corresponding first opening.

According to an embodiment of the invention, in the capacitor structure, the conductive line portion and the contact portions may be integrally formed.

According to an embodiment of the invention, in the capacitor structure, a portion of the first openings may expose the same first electrode layer.

According to an embodiment of the invention, in the capacitor structure, two adjacent first openings may expose different first electrode layers.

According to an embodiment of the invention, the capacitor structure may include a plurality of the second electrode layers. The second dielectric layer may include a plurality of the second openings. The second openings may expose the second electrode layers. The second conductive layer may be a single conductive layer disposed on the second dielectric layer and extending into the second openings.

According to an embodiment of the invention, in the capacitor structure, the second conductive layer may extend into all the second openings.

According to an embodiment of the invention, in the capacitor structure, a portion of the second openings may expose the same second electrode layer.

According to an embodiment of the invention, in the capacitor structure, two adjacent second openings may expose different second electrode layers.

According to an embodiment of the invention, in the capacitor structure, the second conductive layer may include a conductive line portion and at least one contact portion. The at least one contact portion is connected to the conductive line portion. The at least one contact portion is disposed in the at least one second opening.

According to an embodiment of the invention, in the capacitor structure, the conductive line portion and the at least one contact portion may be integrally formed.

According to an embodiment of the invention, in the capacitor structure, the top surface of the first conductive layer and the top surface of the second conductive layer may have the same height.

According to an embodiment of the invention, in the capacitor structure, there may be third openings in the capacitor.

According to an embodiment of the invention, in the capacitor structure, a portion of the second dielectric layer may be disposed in the third openings.

According to an embodiment of the invention, in the capacitor structure, the top-view pattern of the first conductive layer and the top-view pattern of the second conductive layer may match each other.

According to an embodiment of the invention, in the capacitor structure, the top-view pattern of the first conductive layer may include a first comb-shaped portion, the top-view pattern of the second conductive layer may include a second comb-shaped portion, and the first comb-shaped portion and the second comb-shaped portion may match each other.

According to an embodiment of the invention, the capacitor structure may further include a first connection terminal and a second connection terminal. The first connection terminal may be electrically connected to the first electrode layers by the first conductive layer. The second connection terminal may be electrically connected to the at least one second electrode layer by the second conductive layer.

According to an embodiment of the invention, in the capacitor structure, the top-view pattern of the first connection terminal may include a first side, a second side, a third side, and a fourth side. The first side and the third side are opposite to each other. The second side and the fourth side are opposite to each other. The second side is connected to the first side and the third side and is disposed between the first side and the third side. The fourth side is connected to the first side and the third side and is disposed between the first side and the third side. The top-view pattern of the second connection terminal includes a fifth side, a sixth side, a seventh side, and an eighth side. The fifth side and the seventh side are opposite to each other. The sixth side and the eighth side are opposite to each other. The sixth side is connected to the fifth side and the seventh side and is disposed between the fifth side and the seventh side. The eighth side is connected to the fifth side and the seventh side and is disposed between the fifth side and the seventh side.

According to an embodiment of the invention, in the capacitor structure, the top-view pattern of the first conductive layer may include a first main portion, a first extension portion, and a second extension portion. The first main portion is disposed directly below the top-view pattern of the first connection terminal. The first extension portion is connected to the first main portion. The first extension portion is disposed between the top-view pattern of the first connection terminal and the top-view pattern of the second connection terminal and is adjacent to the fifth side of the second connection terminal. The second extension portion is connected to the first main portion. The second extension portion may surround the sixth side, the seventh side, and the eighth side of the second connection terminal. The top-view pattern of the second conductive layer may include a second main portion, a third extension portion, and a fourth extension portion. The second main portion is disposed directly below the top-view pattern of the second connection terminal. The third extension portion is connected to the second main portion. The third extension portion is disposed between the top-view pattern of the first connection terminal and the top-view pattern of the second connection terminal and is adjacent to the first side of the first connection terminal. The fourth extension portion is connected to the second main portion. The fourth extension portion may surround the second side, the third side, and the fourth side of the first connection terminal.

Based on the above description, in the capacitor structure according to the invention, the capacitor includes the first electrode layers, the at least one second electrode layer, and the first dielectric layer. The first electrode layers and the at least one second electrode layer are alternately disposed on the substrate. The first dielectric layer is disposed between the first electrode layer and the second electrode layer. The second dielectric layer has the first openings exposing the first electrode layers. The first conductive layer is electrically connected to the first electrode layers. The first conductive layer is a single conductive layer disposed on the second dielectric layer and extending into the first openings. In this way, the first electrode layers can be electrically connected to each other by the first conductive layer, thereby effectively reducing the process complexity and the manufacturing cost.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A and FIG. 1B are cross-sectional views illustrating a capacitor structure according to some embodiments of the invention.

FIG. 1C is a cross-sectional view illustrating some components in the capacitor structure of FIG. 1A.

FIG. 1D is a cross-sectional view illustrating some components in the capacitor structure of FIG. 1A.

FIG. 2A and FIG. 2B are top views illustrating conductive layers and connection terminals according to some embodiments of the invention.

FIG. 2C is a top view illustrating a capacitor structure according to some embodiments of the invention.

FIG. 3A and FIG. 3B are top views illustrating conductive layers and connection terminals according to other embodiments of the invention.

FIG. 3C is a top view illustrating a capacitor structure according to other embodiments of the invention.

FIG. 4A and FIG. 4B are top views illustrating conductive layers and connection terminals according to other embodiments of the invention.

FIG. 4C is a top view illustrating a capacitor structure according to other embodiments of the invention.

FIG. 5A and FIG. 5B are cross-sectional views illustrating a capacitor structure according to other embodiments of the invention.

FIG. 5C is a cross-sectional view illustrating some components in the capacitor structure of FIG. 5A.

FIG. 5D is a cross-sectional view illustrating some components in the capacitor structure of FIG. 5A.

FIG. 6A and FIG. 6B are top views illustrating conductive layers and connection terminals according to other embodiments of the invention.

FIG. 6C is a top view illustrating a capacitor structure according to other embodiments of the invention.

FIG. 7A and FIG. 7B are top views illustrating conductive layers and connection terminals according to other embodiments of the invention.

FIG. 7C is a top view illustrating a capacitor structure according to other embodiments of the invention.

FIG. 8A and FIG. 8B are top views illustrating conductive layers and connection terminals according to other embodiments of the invention.

FIG. 8C is a top view illustrating a capacitor structure according to other embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. Furthermore, the features in the top view and the features in the cross-sectional view are not drawn to the same scale. In fact, the dimensions of the various features may be arbitrarily increased or reduced for clarity of discussion.

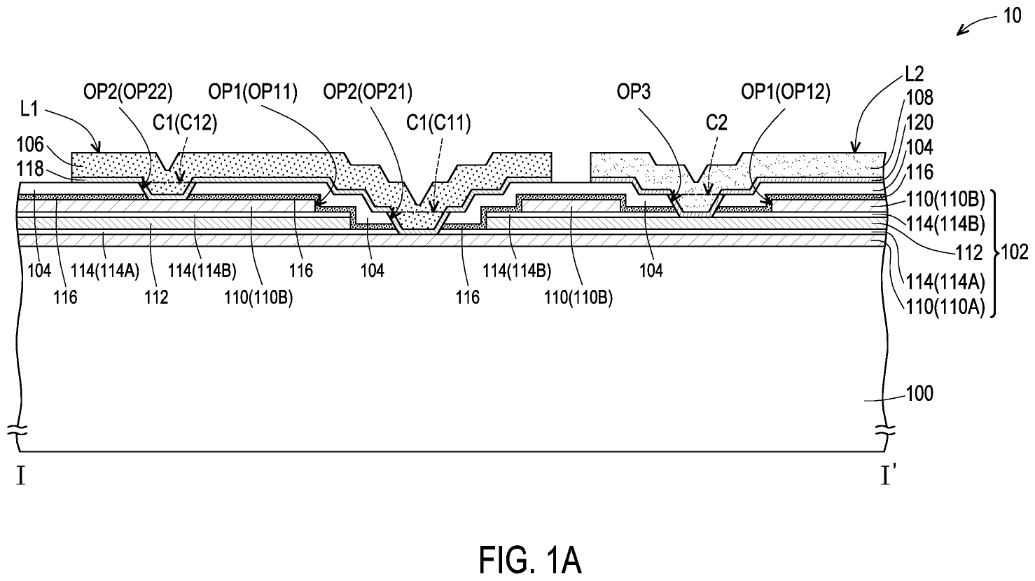

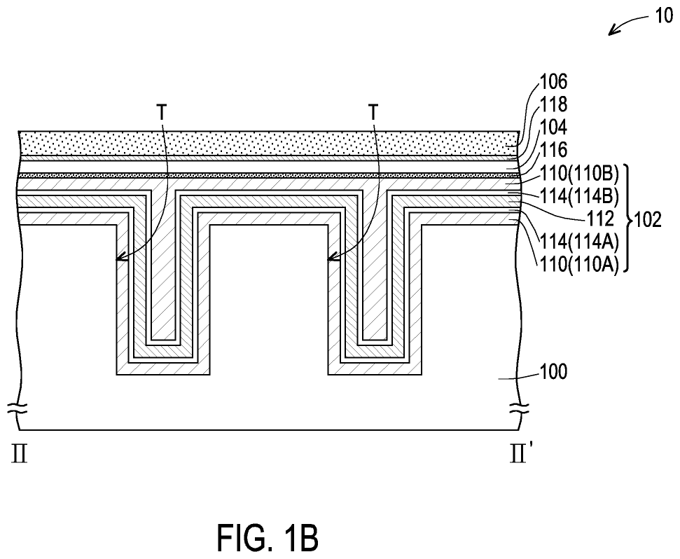

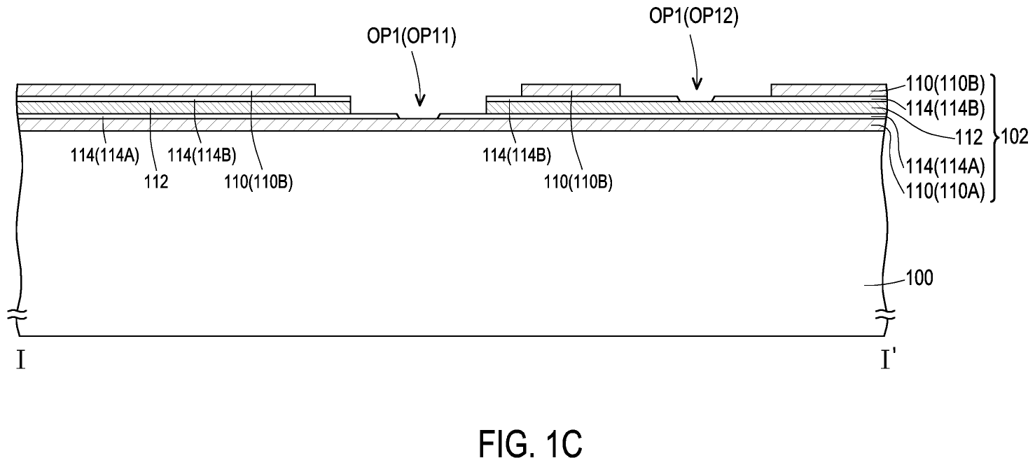

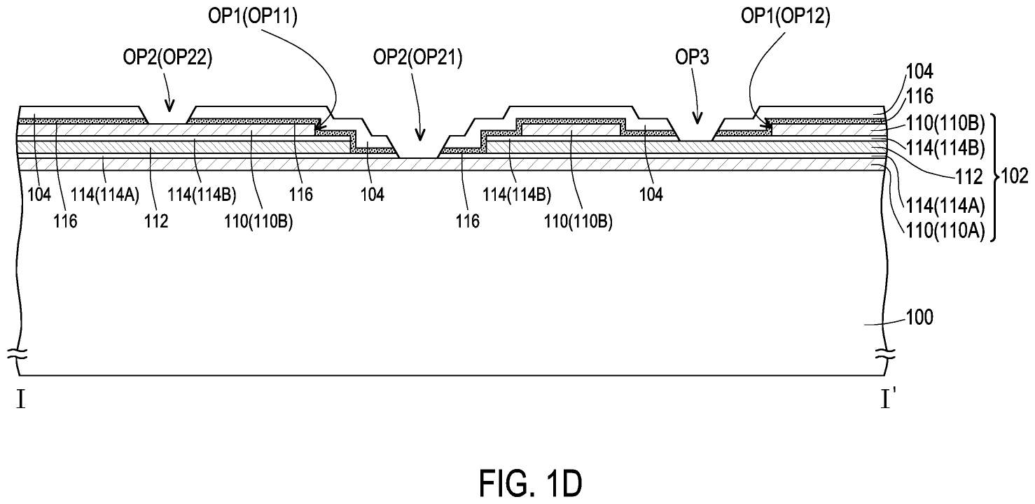

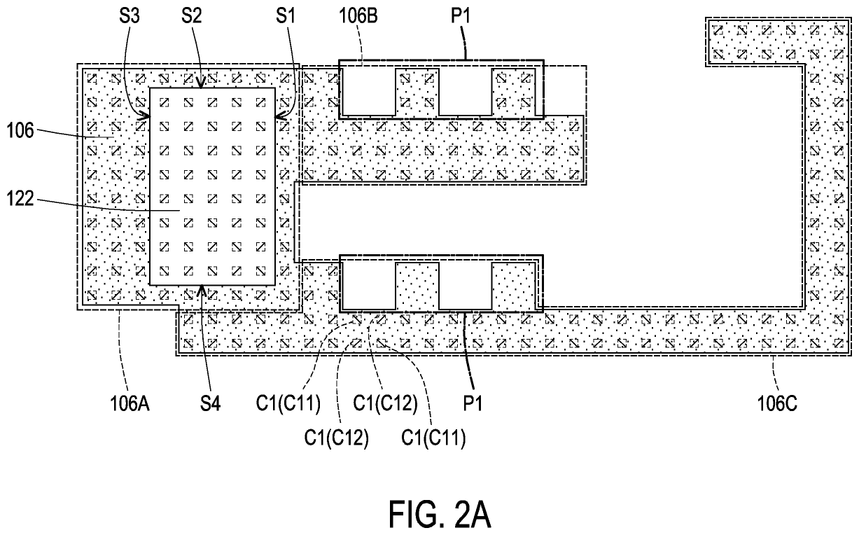

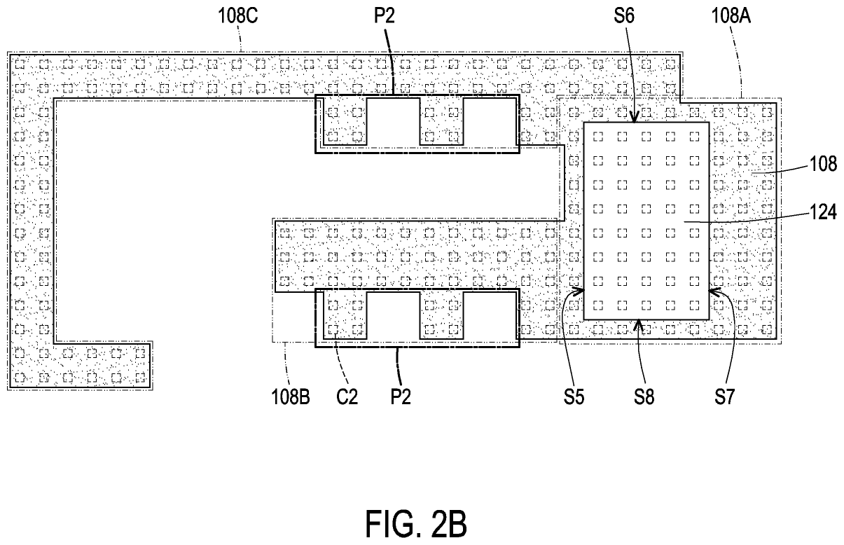

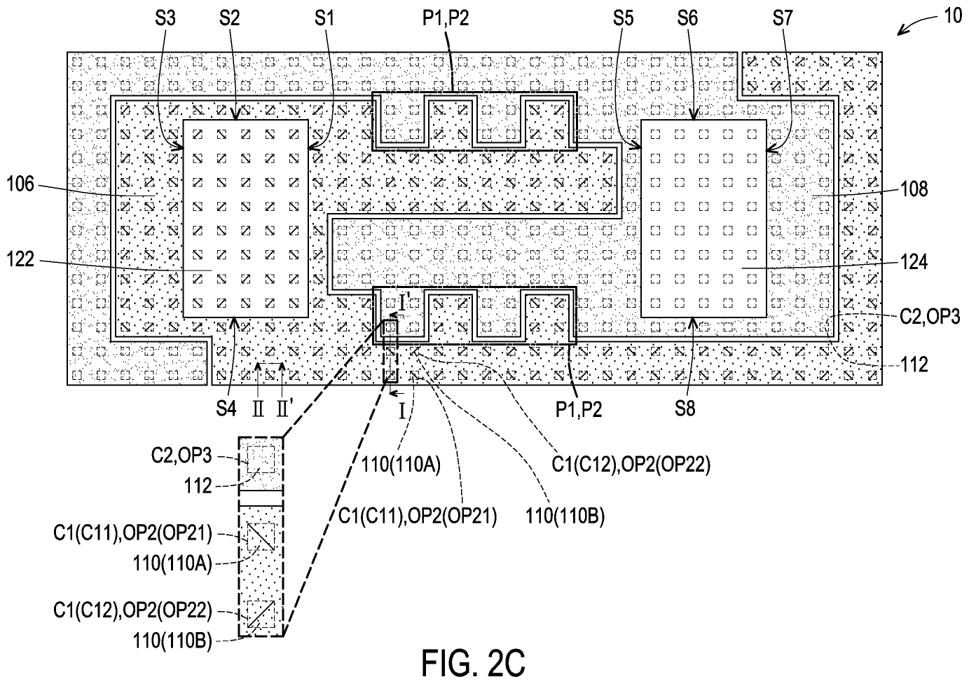

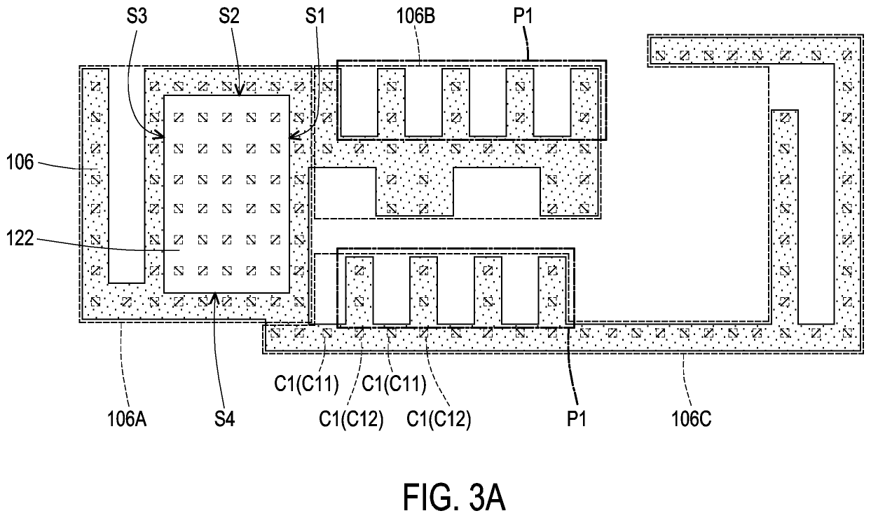

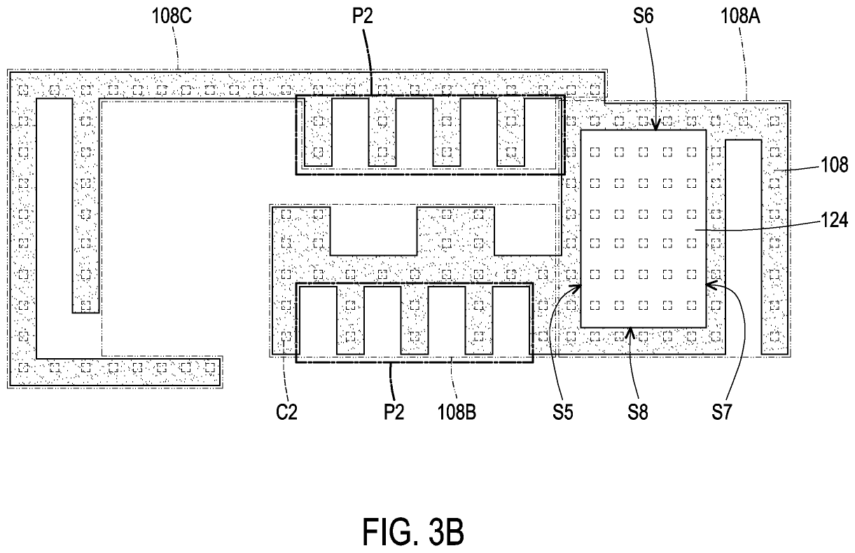

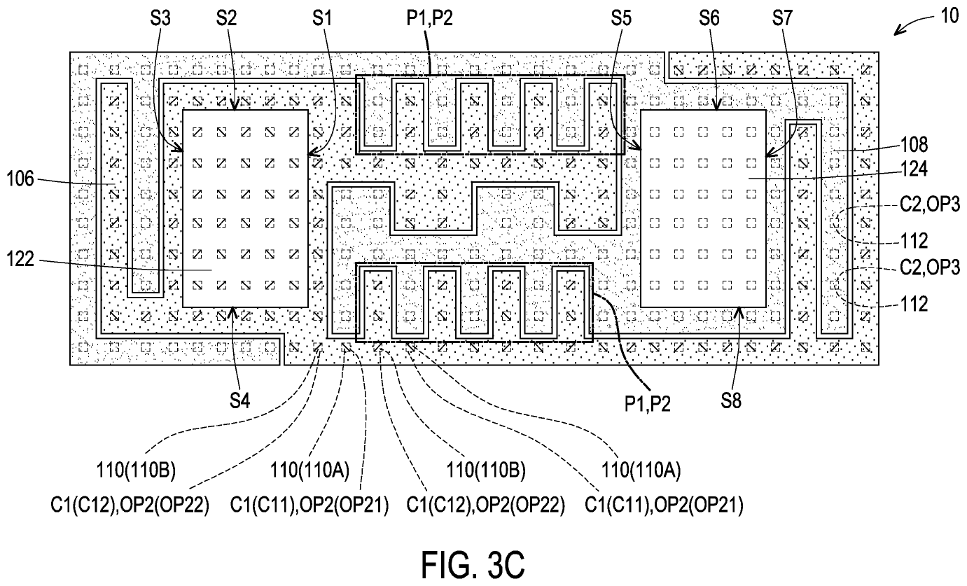

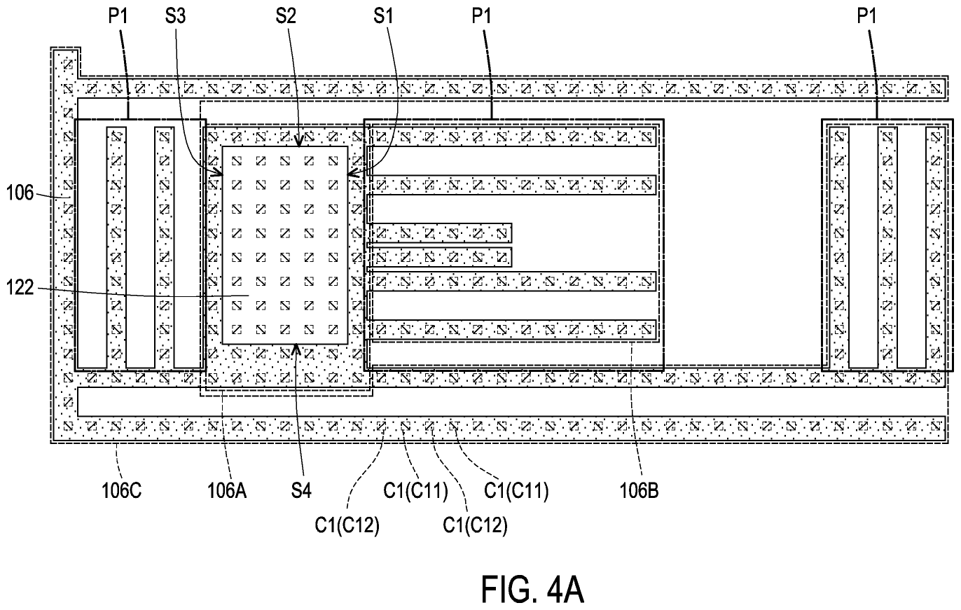

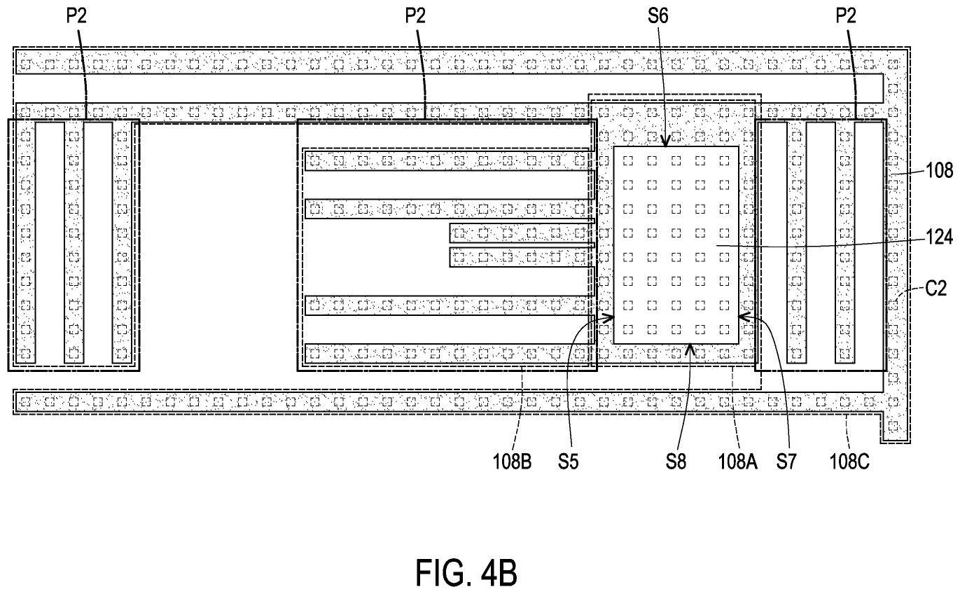

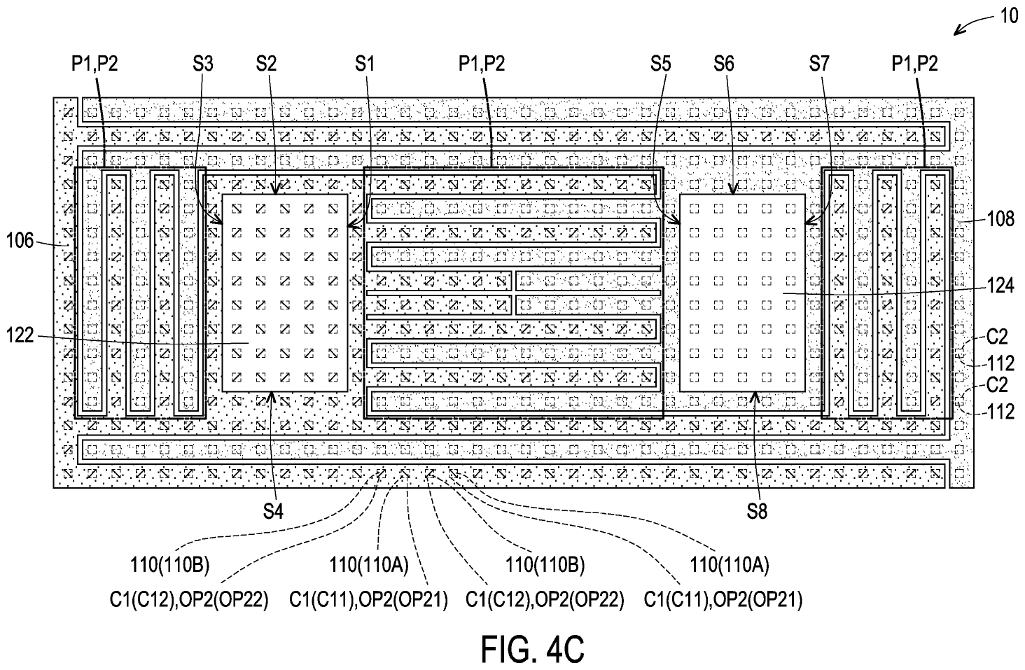

FIG. 1A and FIG. 1B are cross-sectional views illustrating a capacitor structure according to some embodiments of the invention. FIG. 1C is a cross-sectional view illustrating some components in the capacitor structure of FIG. 1A. In FIG. 1C, some components in FIG. 1A are omitted to clearly illustrate the configuration of the opening OP1. FIG. 1D is a cross-sectional view illustrating some components in the capacitor structure of FIG. 1A. In FIG. 1D, some components in FIG. 1A are omitted to clearly illustrate the configuration of the opening OP2 and the opening OP3. FIG. 2A and FIG. 2B are top views illustrating conductive layers and connection terminals according to some embodiments of the invention. FIG. 2C is a top view illustrating a capacitor structure according to some embodiments of the invention. FIG. 1A, FIG. 1C, and FIG. 1D are cross-sectional views taken along section line I-I′ in FIG. 2C. FIG. 1B is a cross-sectional view taken along section line II-II′ in FIG. 2C. FIG. 3A and FIG. 3B are top views illustrating conductive layers and connection terminals according to other embodiments of the invention. FIG. 3C is a top view illustrating a capacitor structure according to other embodiments of the invention. FIG. 4A and FIG. 4B are top views illustrating conductive layers and connection terminals according to other embodiments of the invention. FIG. 4C is a top view illustrating a capacitor structure according to other embodiments of the invention. In the top view of the above embodiments, some components in the cross-sectional view are omitted to clearly illustrate the configuration relationship between the components in the top view.

Referring to FIG. 1A, FIG. 1B, FIG. 1C, FIG. 1D, FIG. 2A, FIG. 2B, and FIG. 2C, a capacitor structure 10 includes a substrate 100, a capacitor 102, a dielectric layer 104, a conductive layer 106, and a conductive layer 108. In some embodiments, the capacitor structure 10 may be a silicon capacitor. In some embodiments, the substrate 100 may be a semiconductor substrate such as a silicon substrate. In some embodiments, the substrate 100 may have a trench T (FIG. 1). In some embodiments, the substrate 100 may have an N-type conductivity type or a P-type conductivity type. In the present embodiment, the substrate 100 may have the N-type conductivity type, for example, but the invention is not limited thereto.

The capacitor 102 is disposed on the substrate 100. In some embodiments, the capacitor 102 may be further disposed in the trench T. The capacitor 102 includes electrode layers 110 (e.g., electrode layer 110A and electrode layer 110B), at least one electrode layer 112 and dielectric layers 114. The electrode layers 110 and the at least one electrode layer 112 are alternately disposed on the substrate 100. The dielectric layer 114 is disposed between the electrode layer 110 and the electrode layer 112. In some embodiments, the dielectric layer 114A is disposed between the electrode layer 110A and the electrode layer 112. In some embodiments, the dielectric layer 114B is disposed between the electrode layer 110B and the electrode layer 112. The electrode layer 110 and the electrode layer 112 may be insulated from each other by the dielectric layer 114. In some embodiments, the bottommost electrode layer 110 (e.g., electrode layer 110A) may be the layer closest to the substrate 100 in the capacitor 102.

In some embodiments, there may be openings OP1 (e.g., opening OP11 and opening OP12) in the capacitor 102. In some embodiments, the opening OP11 may be located in the dielectric layer 114A, the electrode layer 112, the dielectric layer 114B, and the electrode layer 110B. In some embodiments, the opening OP11 may expose the top surface of the electrode layer 110A, the sidewall of the dielectric layer 114A, the top surface of the dielectric layer 114A, the sidewall of the electrode layer 112, the sidewall of the dielectric layer 114B, the top surface of the dielectric layer 114B, and the sidewall of the electrode layer 110B. In some embodiments, the cross-sectional shape of the opening OP11 may include a stepped shape, but the invention is not limited thereto.

In some embodiments, the opening OP 12 may be located in the dielectric layer 114B and the electrode layer 110B. In some embodiments, the opening OP 12 may expose the top surface of the electrode layer 112, the sidewall of the dielectric layer 114B, the top surface of the dielectric layer 114B, and the sidewall of the electrode layer 110B. In some embodiments, the cross-sectional shape of the opening OP12 may include a stepped shape, but the invention is not limited thereto.

In the present embodiment, the number of the electrode layers 110 is, for example, two, but the invention is not limited thereto. As long as the number of the electrode layers 110 is at least two, it falls within the scope of the invention. In other embodiments, the number of the electrode layers 110 may be three or more. In the present embodiment, the number of the electrode layers 112 is, for example, one, but the invention is not limited thereto. As long as the number of the electrode layers 112 is at least one, it falls within the scope of the invention. In other embodiments, the number of the electrode layers 112 may be two or more. In the present embodiment, the number of the dielectric layers 114 is, for example, two, but the invention is not limited thereto. As long as the number of the dielectric layers 114 is at least two, it falls within the scope of the invention. In other embodiments, the number of the dielectric layers 114 may be three or more.

In some embodiments, the electrode layer 110 and the substrate 100 may have the same conductivity type (e.g., N type). In some embodiments, the material of the electrode layer 110 is, for example, doped polysilicon. In some embodiments, the electrode layer 112 and the substrate 100 may have the same conductivity type (e.g., N type). In some embodiments, the material of the electrode layer 112 is, for example, doped polysilicon. In some embodiments, the material of the dielectric layer 114 is, for example, silicon oxide, silicon nitride, a high dielectric constant material, or a combination thereof. For example, the dielectric layer 114 is a silicon oxide layer, a silicon nitride layer, a composite layer of silicon oxide layer/silicon nitride layer (ON), a composite layer of silicon oxide layer/silicon nitride layer/silicon oxide layer (ONO), a high dielectric constant material layer, or a composite layer of high dielectric constant material layers.

The dielectric layer 104 is disposed on the electrode layers 110 and the electrode layer 112 and has openings OP2 (e.g., opening OP21 and opening OP22) and at least one opening OP3. A portion of the dielectric layer 104 may be disposed in the openings OP1. In the present embodiment, as shown in FIG. 2C, the number of the openings OP21 is, for example, plural, but the invention is not limited thereto. As long as the number of the openings OP21 is at least one, it falls within the scope of the invention. In the present embodiment, as shown in FIG. 2C, the number of the openings OP22 is, for example, plural, but the invention is not limited thereto. As long as the number of the openings OP22 is at least one, it falls within the scope of the invention. In the present embodiment, as shown in FIG. 2C, the number of the openings OP3 is, for example, plural, but the invention is not limited thereto. As long as the number of the openings OP3 is at least one, it falls within the scope of the invention. In some embodiments, the material of the dielectric layer 104 is, for example, silicon oxide or borophosphosilicate glass (BPSG).

The openings OP2 expose the electrode layers 110. That is, the opening OP2 may pass through the dielectric layer 104 to extend to the top surface of the electrode layer 110. In some embodiments, each of the openings OP2 exposes the corresponding electrode layer 110. In some embodiments, two adjacent openings OP2 may expose different electrode layers 110. For example, the opening OP21 may expose the electrode layer 110A, and the opening OP22 may expose the electrode layer 110B. In some embodiments, a portion of the openings OP2 may expose the same electrode layer 110. For example, as shown in FIG. 2C, the openings OP21 may expose the same electrode layer 110A. For example, as shown in FIG. 2C, the openings OP22 may expose the same electrode layer 110B. In some embodiments, the sidewall of the opening OP2 may be an inclined surface.

The opening OP3 exposes the electrode layer 112. That is, the opening OP3 may pass through the dielectric layer 104 to extend to the top surface of the electrode layer 112. In some embodiments, as shown in FIG. 2C, the openings OP3 may expose the same electrode layer 112.

In some embodiments, the sidewall of the opening OP3 may be an inclined surface.

In some embodiments, the capacitor structure 10 may further include a stop layer 116. The stop layer 116 is disposed between the dielectric layer 104 and the electrode layer 110 and between the dielectric layer 104 and the electrode layer 112. The stop layer 116 may be further disposed between the dielectric layer 104 and the dielectric layer 114. In addition, a portion of the stop layer 116 may be disposed in the openings OP1. Furthermore, the opening OP2 and the opening OP3 may further pass through the stop layer 116. In some embodiments, the material of the stop layer 116 is, for example, silicon oxide, silicon nitride, silicon oxynitride, or a combination thereof. In some embodiments, the material of the stop layer 116 is, for example, a composite material of silicon oxide/silicon nitride (ON).

The conductive layer 106 is electrically connected to the electrode layers 110. The conductive layer 106 is a single conductive layer disposed on the dielectric layer 104 and extending into the openings OP2. In this way, the electrode layers 110 can be electrically connected to each other by the conductive layer 106, thereby effectively reducing the process complexity and the manufacturing cost. In some embodiments, the conductive layer 106 may extend into all the openings OP2. That is, the conductive layer 106 may extend into all the openings OP21 and all the openings OP22. In some embodiments, the conductive layer 106 may be integrally formed. In some embodiments, the material of the conductive layer 106 is, for example, metal or metal compound, such as aluminum, copper, aluminum-copper alloy, or aluminum-silicon-copper alloy.

In some embodiments, the conductive layer 106 may include a conductive line portion L1 and contact portions C1 (e.g., contact portion C11 and contact portion C12). The contact portions C1 are connected to the conductive line portion L1. In some embodiments, the conductive line portion L1 and the contact portions C1 may be integrally formed. Each of the contact portions C1 may be disposed in the corresponding opening OP2. In some embodiments, the contact portion C11 may be disposed in the corresponding opening OP21, and the contact portion C12 may be disposed in the corresponding opening OP22. In the present embodiment, as shown in FIG. 2A and FIG. 2C, the number of the contact portions C11 is, for example, plural, and the number of the contact portions C12 is, for example, plural, but the invention is not limited thereto. As long as the number of the contact portions C11 is at least one, and the number of the contact portions C12 is at least one, it falls within the scope of the invention. In addition, when the number of the contact portions C11 is plural, the equivalent series resistance (ESR) can be effectively reduced. Furthermore, when the number of the contact portions C12 is plural, the equivalent series resistance can be effectively reduced. In some embodiments, as shown in FIG. 2A and FIG. 2C, the contact portions C11 and the contact portions C12 may be alternately arranged.

The conductive layer 108 is electrically connected to the electrode layer 112. The conductive layer 108 is disposed on the dielectric layer 104 and in the opening OP3. In some embodiments, the top surface of the conductive layer 106 and the top surface of the conductive layer 108 may have the same height. In some embodiments, the conductive layer 108 may be a single conductive layer disposed on the dielectric layer 104 and extending into the openings OP3. In some embodiments, the conductive layer 108 may extend into all the openings OP3. In some embodiments, the conductive layer 108 may be integrally formed. In some embodiments, the material of the conductive layer 108 is, for example, metal or metal compound, such as aluminum, copper, aluminum-copper alloy, or aluminum-silicon-copper alloy.

In some embodiments, the conductive layer 108 may include a conductive line portion L2 and at least one contact portion C2. In the present embodiment, as shown in FIG. 2B and FIG. 2C, the number of the contact portions C2 is, for example, plural, but the invention is not limited thereto. As long as the number of the contact portions C2 is at least one, it falls within the scope of the invention. The contact portion C2 is connected to the conductive line portion L2. In some embodiments, the conductive line portion L2 and the contact portion C2 may be integrally formed. Each of the contact portions C2 may be disposed in the corresponding opening OP3. In addition, when the number of the contact portions C2 is plural, the equivalent series resistance can be effectively reduced.

In some embodiments, the trench T may not be located in the substrate 100 directly below the contact portion C1 and may not be located in the substrate 100 directly below the contact portion C2.

In some embodiments, the capacitor structure 10 may further include a barrier layer 118 and a barrier layer 120. The barrier layer 118 is disposed between the conductive layer 106 and the dielectric layer 104, between the conductive layer 106 and the stop layer 116, and between the conductive layer 106 and the electrode layer 110. In some embodiments, the barrier layer 118 may be a single barrier layer disposed on dielectric layer 104 and extending into the openings OP2. In some embodiments, the conductive layer 106 may be electrically connected to the electrode layer 110 by the barrier layer 118. In some embodiments, the material of the barrier layer 118 is, for example, titanium, titanium nitride, or a combination thereof.

The barrier layer 120 is disposed between the conductive layer 108 and the dielectric layer 104, between the conductive layer 108 and the stop layer 116, between the conductive layer 108 and the dielectric layer 114, and between the conductive layer 108 and the electrode layer 112. In some embodiments, the barrier layer 120 may be a single barrier layer disposed on the dielectric layer 104 and extending into the openings OP3. In some embodiments, the conductive layer 108 may be electrically connected to the electrode layer 112 by the barrier layer 120. In some embodiments, the material of the barrier layer 120 is, for example, titanium, titanium nitride, or a combination thereof.

In some embodiments, the conductive layer 106 and the conductive layer 108 may be simultaneously formed by the same process. That is, the conductive layer 106 and the conductive layer 108 may be derived from the same conductive material layer. In some embodiments, the barrier layer 118 and the barrier layer 120 may be simultaneously formed by the same process. That is, the barrier layer 118 and the barrier layer 120 may be derived from the same barrier material layer. For example, the method of forming the conductive layer 106, the conductive layer 108, the barrier layer 118, and the barrier layer 120 may include the following steps, but the invention is not limited thereto. First, a barrier material layer (not shown) and a conductive material layer (not shown) may be sequentially formed on the dielectric layer 104, and the barrier material layer and the conductive material layer fills the opening OP2 and opening OP3. Then, the conductive material layer and the barrier material layer may be patterned to form the conductive layer 106, the conductive layer 108, the barrier layer 118, and the barrier layer 120.

In some embodiments, the capacitor structure 10 may further include a connection terminal 122 and a connection terminal 124. The connection terminal 122 may be electrically connected to the electrode layers 110 by the conductive layer 106. The connection terminal 124 may be electrically connected to the electrode layer 112 by the conductive layer 108. In some embodiments, the connection terminal 122 and the connection terminal 124 may be the outermost layers of the capacitor structure 10. That is, the top surface of the connection terminal 122 and the top surface of the connection terminal 124 may not be covered by other components in the capacitor structure 10. In some embodiments, each of the connection terminal 122 and the connection terminal 124 is, for example, a under-bump metallization (UBM), a bump, or a combination thereof. In some embodiments, the material of each of the connection terminal 122 and the connection terminal 124 is, for example, titanium, nickel, gold, copper, tin, or a combination thereof.

In some embodiments, the top-view pattern of the connection terminal 122 may be a rectangle, but the invention is not limited thereto. In other embodiments, the top-view pattern of the connection terminal 122 may be other polygon, a circle, or an ellipse. In some embodiments, when the top-view pattern of the connection terminal 122 is a rectangle, the top-view pattern of the connection terminal 122 may include a first side S1, a second side S2, a third side S3, and a fourth side S4. The first side S1 and the third side S3 are opposite to each other. The second side S2 and the fourth side S4 are opposite to each other. The second side S2 is connected to the first side S1 and the third side S3 and is disposed between the first side S1 and the third side S3. The fourth side S4 is connected to the first side S1 and the third side S3 and is disposed between the first side S1 and the third side S3.

In some embodiments, the top-view pattern of the connection terminal 124 may be a rectangle, but the invention is not limited thereto. In other embodiments, the top-view pattern of the connection terminal 124 may be other polygon, a circle, or an ellipse. In some embodiments, when the top-view pattern of the connection terminal 124 is a rectangle, the top-view pattern of the connection terminal 124 includes a fifth side S5, a sixth side S6, a seventh side S7, and an eighth side S8. The fifth side S5 and the seventh side S7 are opposite to each other. The sixth side S6 and the eighth side S8 are opposite to each other. The sixth side S6 is connected to the fifth side S5 and the seventh side S7 and is disposed between the fifth side S5 and the seventh side S7. The eighth side S8 is connected to the fifth side S5 and the seventh side S7 and is disposed between the fifth side S5 and the seventh side S7.

As shown in FIG. 2A, FIG. 2B, and FIG. 2C, the top-view pattern of the conductive layer 106 may include a main portion 106A, an extension portion 106B, and an extension portion 106C. The main portion 106A is disposed directly below the top-view pattern of the connection terminal 122. In some embodiments, the main portion 106A may include the contact portions C1. The extension portion 106B is connected to the main portion 106A. The extension portion 106B is disposed between the top-view pattern of the connection terminal 122 and the top-view pattern of the connection terminal 124 and is adjacent to the fifth side S5 of the connection terminal 124. In some embodiments, the extension portion 106B may include the contact portions C1. The extension portion 106C is connected to the main portion 106A. The extension portion 106C may surround the connection terminal 124. In some embodiments, the extension portion 106C may surround the sixth side S6, the seventh side S7, and the eighth side S8 of the connection terminal 124. In some embodiments, extension portion 106C may include the contact portions C1.

As shown in FIG. 2A, FIG. 2B, and FIG. 2C, the top-view pattern of the conductive layer 108 may include a main portion 108A, an extension portion 108B, and an extension portion 108C. The main portion 108A is disposed directly below the top-view pattern of the connection terminal 124. In some embodiments, the main portion 108A may include the contact portions C2. The extension portion 108B is connected to the main portion 108A. The extension portion 108B is disposed between the top-view pattern of the connection terminal 122 and the top-view pattern of the connection terminal 124 and is adjacent to the first side S1 of the connection terminal 122. In some embodiments, the extension portion 108B may include the contact portions C2. The extension portion 108C is connected to the main portion 108A. The extension portion 108C may surround the connection terminal 122. In some embodiments, the extension portion 108C may surround the second side S2, the third side S3, and the fourth side S4 of the connection terminal 122. In some embodiments, the extension portion 108C may include the contact portions C2.

In some embodiments, as shown in FIG. 2A, FIG. 2B, and FIG. 2C, the top-view pattern of the conductive layer 106 and the top-view pattern of the conductive layer 108 may match each other. In some embodiments, the top-view pattern of the conductive layer 106 may include a comb-shaped portion P1, the top-view pattern of the conductive layer 108 may include a comb-shaped portion P2, and the comb-shaped portion P1 and the comb-shaped portion P2 may match each other. In some embodiments, as shown in FIG. 2A, FIG. 2B, and FIG. 2C, the extension portion 106B may include the comb-shaped portion P1, the extension portion 108C may include the comb-shaped portion P2, and the comb-shaped portion P1 of the extension portion 106B and the comb-shaped portion P2 of the extension portion 108C may match each other. In some embodiments, as shown in FIG. 2A, FIG. 2B, and FIG. 2C, the extension portion 106C may include the comb-shaped portion P1, the extension portion 108B may include the comb-shaped portion P2, and the comb-shaped portion P1 of the extension portion 106C and the comb-shaped portion P2 of the extension portion 108B may match each other.

In addition, the top-view pattern of the conductive layer 106 is not limited to the top-view pattern as shown in FIG. 2A and FIG. 2C. In other embodiments, the top-view pattern of the conductive layer 106 may be the top-view pattern as shown in FIG. 3A, FIG. 3C, FIG. 4A, or FIG. 4C, and the description thereof is omitted here. Furthermore, the top-view pattern of the conductive layer 108 is not limited to the top-view pattern as shown in FIG. 2B and FIG. 2C. In other embodiments, the top-view pattern of the conductive layer 108 may be the top-view pattern as shown in FIG. 3B, FIG. 3C, FIG. 4B, or FIG. 4C, and the description thereof is omitted here.

Based on the above embodiments, in the capacitor structure 10, the capacitor 102 includes the electrode layers 110, the at least one electrode layer 112, and the dielectric layer 114. The electrode layers 110 and the at least one electrode layer 112 are alternately disposed on the substrate 100. The dielectric layer 114 is disposed between the electrode layer 110 and the electrode layer 112. The dielectric layer 104 has the openings OP2 exposing the electrode layers 110. The conductive layer 106 is electrically connected to the electrode layers 110. The conductive layer 106 is a single conductive layer disposed on the dielectric layer 104 and extending into the openings OP2. In this way, the electrode layers 110 can be electrically connected to each other by the conductive layer 106, thereby effectively reducing the process complexity and the manufacturing cost.

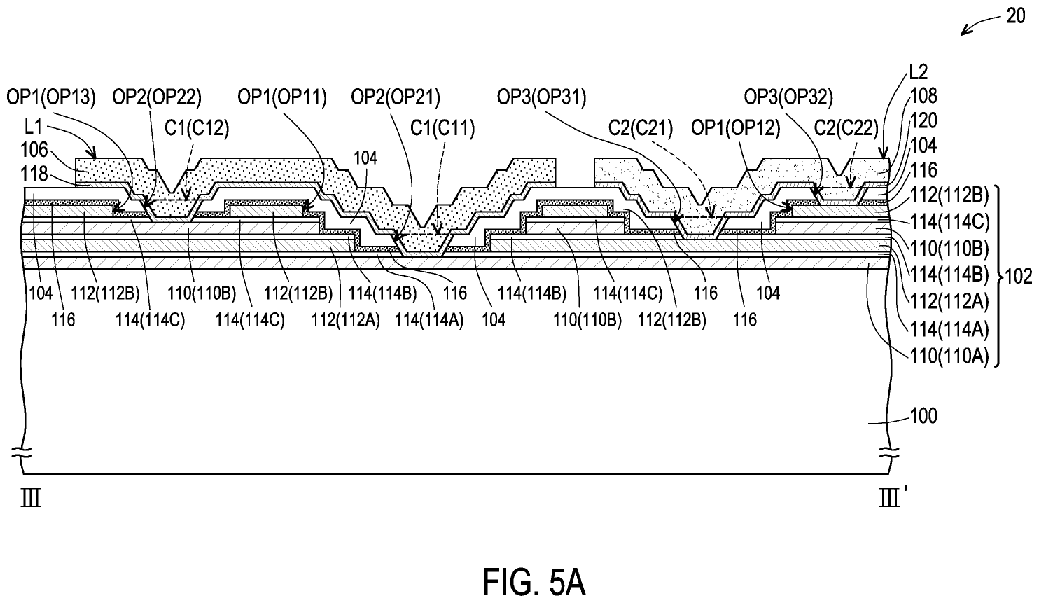

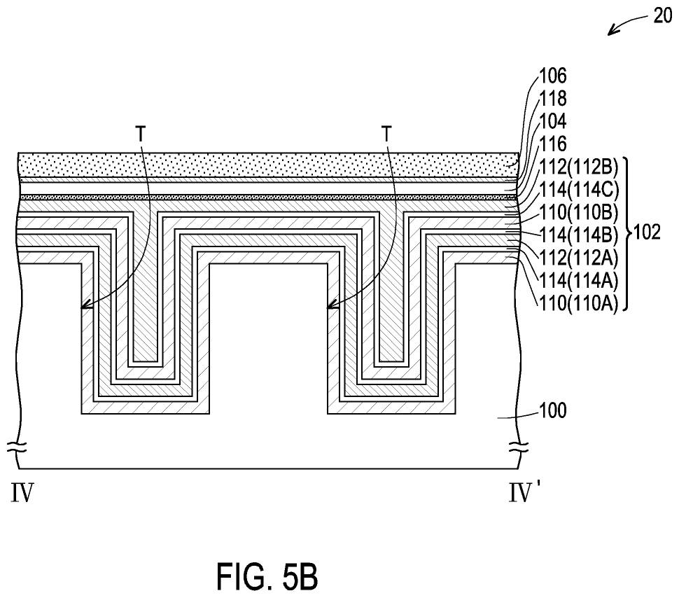

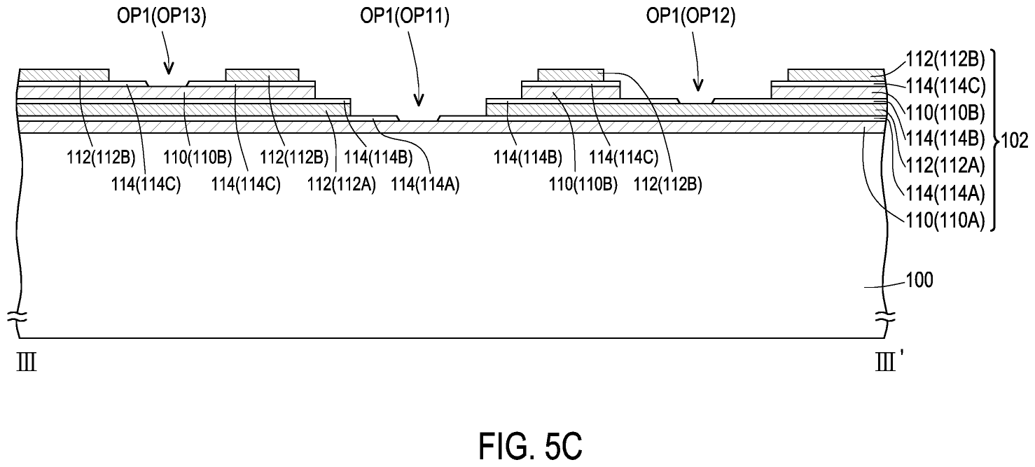

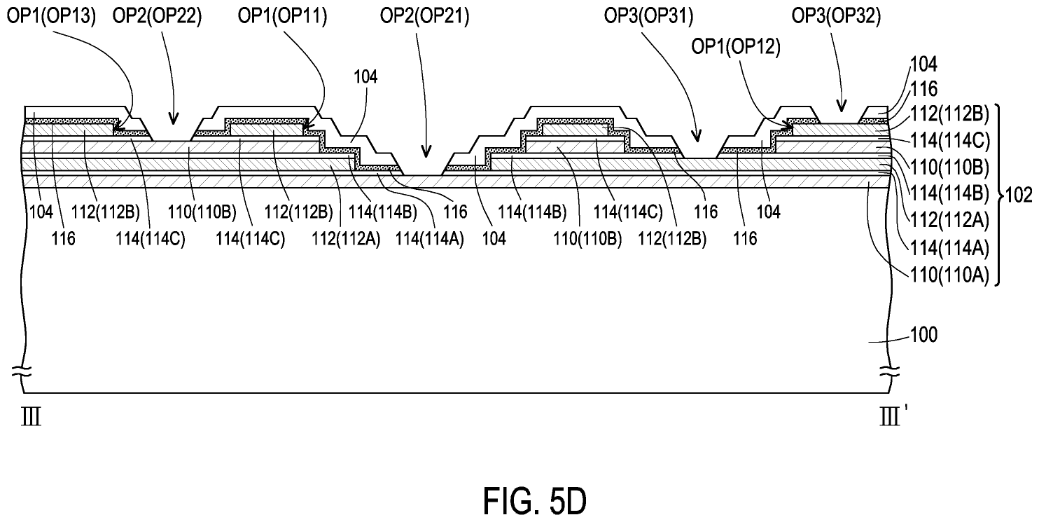

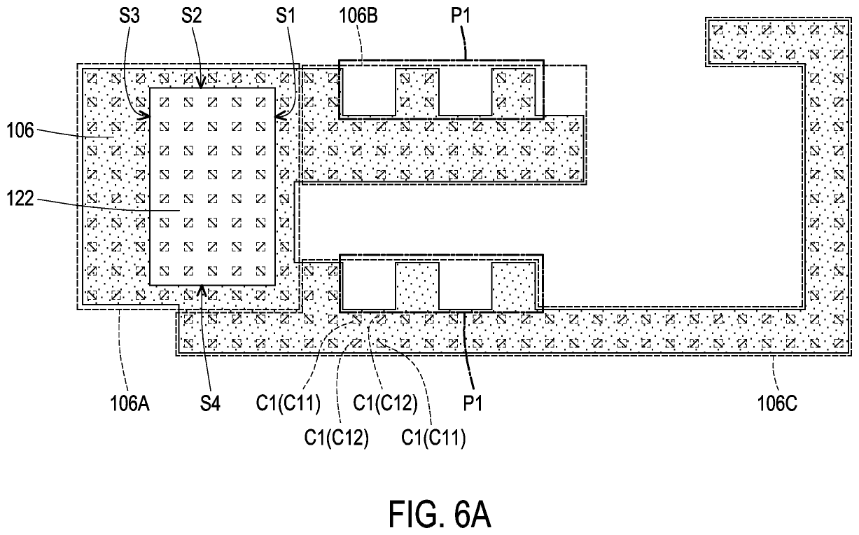

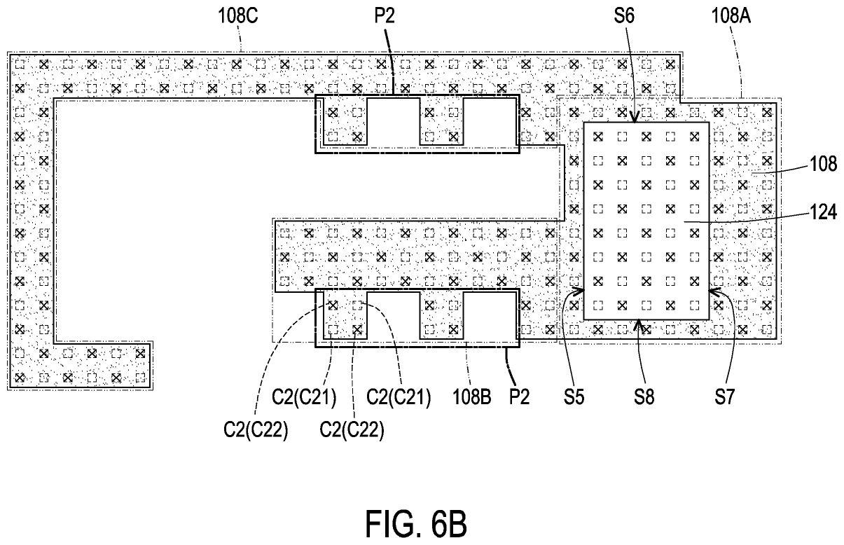

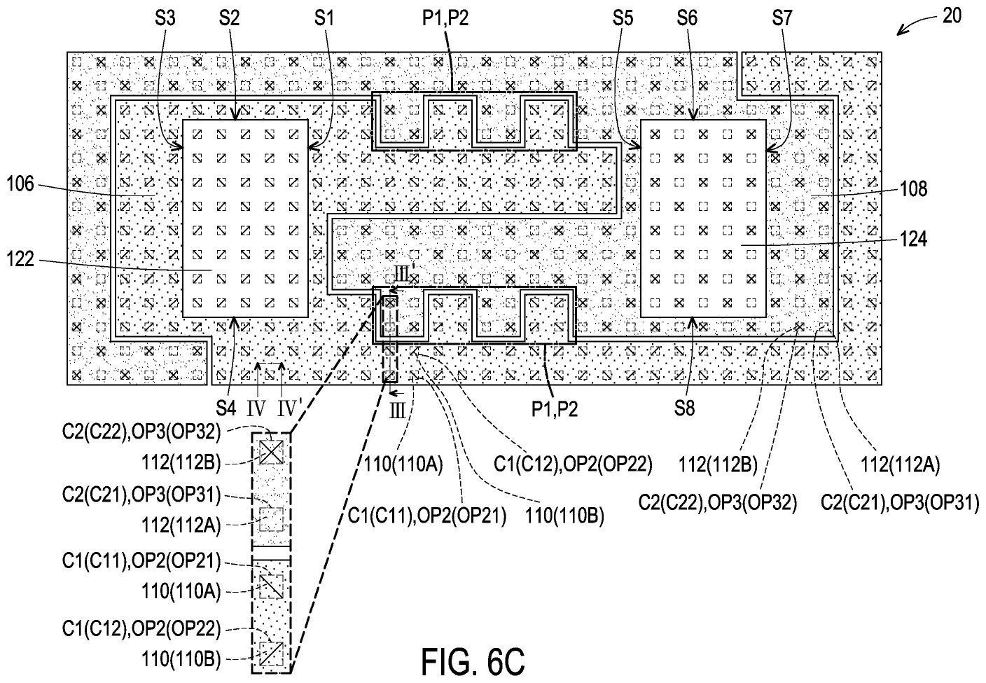

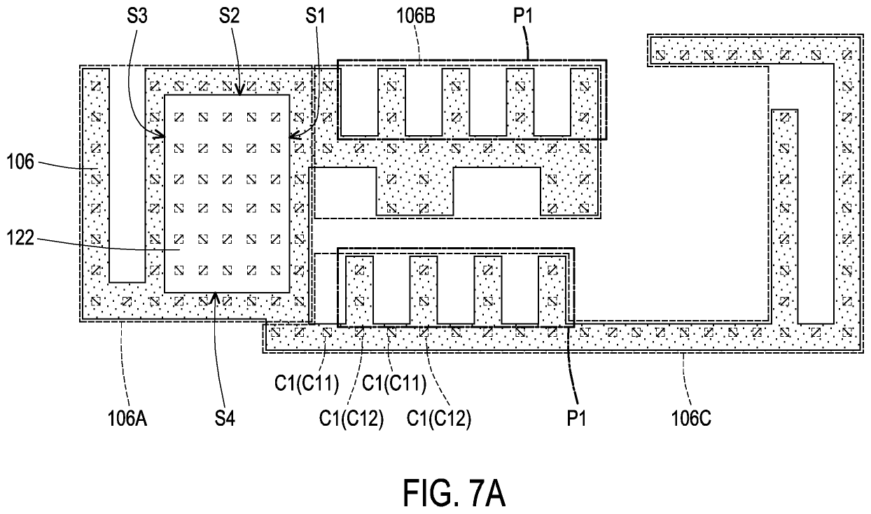

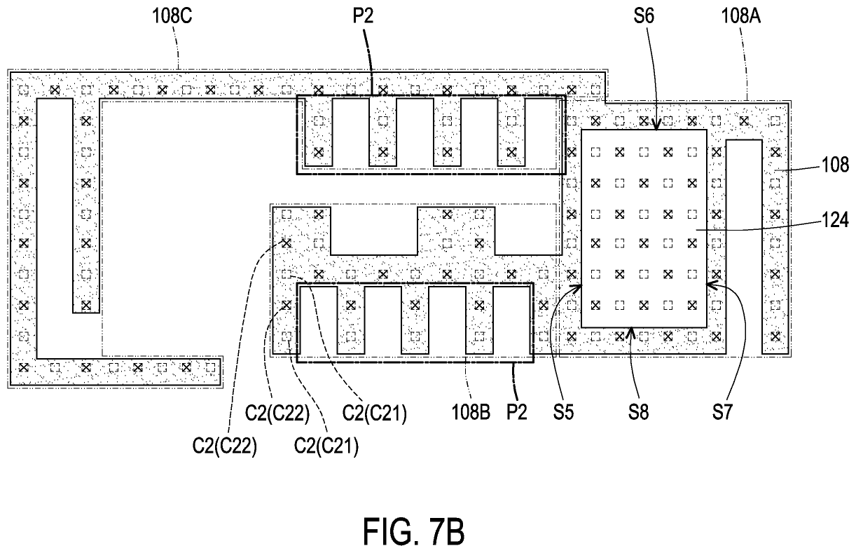

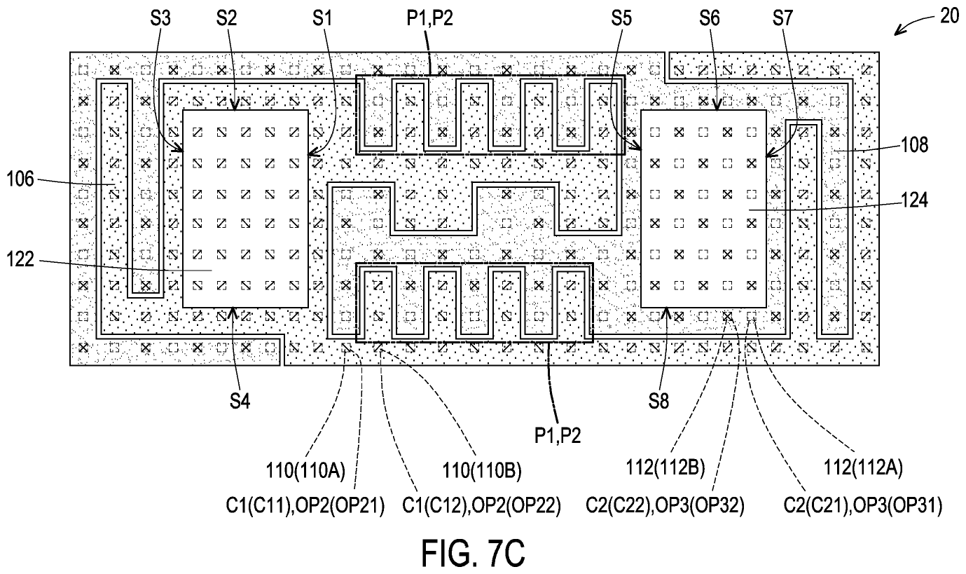

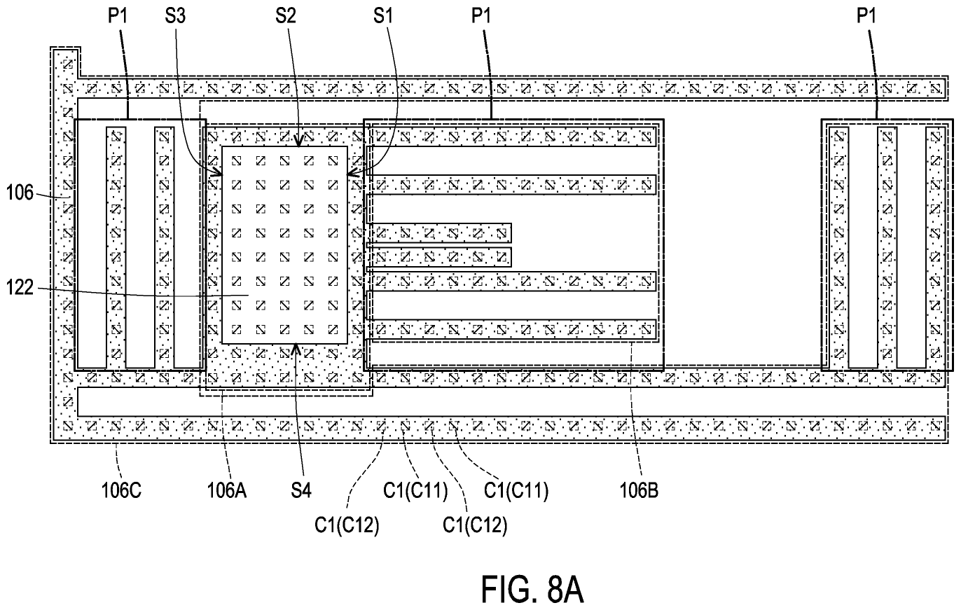

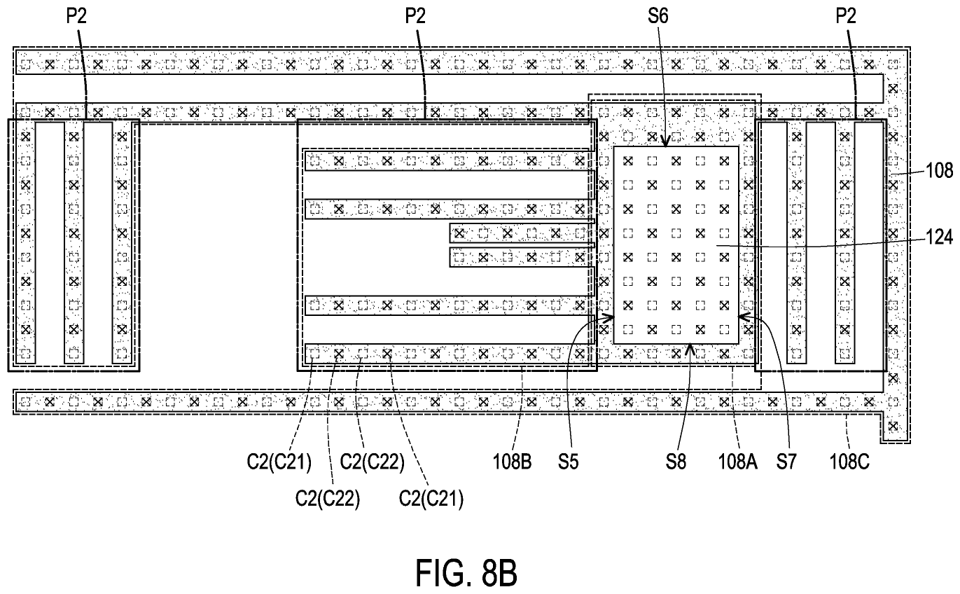

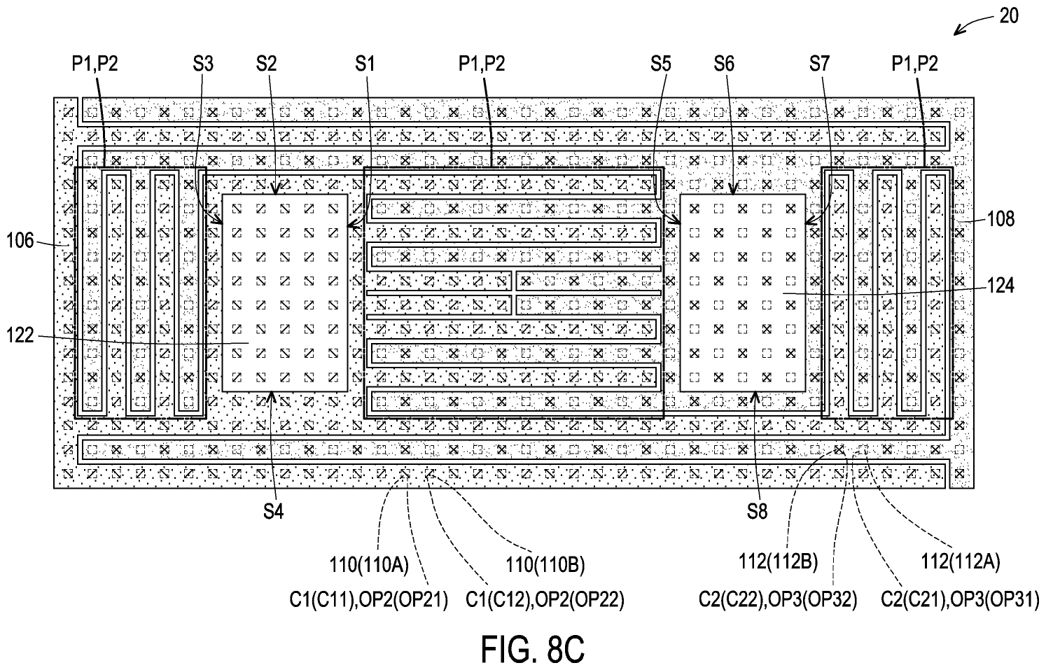

FIG. 5A and FIG. 5B are cross-sectional views illustrating a capacitor structure according to other embodiments of the invention. FIG. 5C is a cross-sectional view illustrating some components in the capacitor structure of FIG. 5A. In FIG. 5C, some components in FIG. 5A are omitted to clearly illustrate the configuration of the opening OP1. FIG. 5D is a cross-sectional view illustrating some components in the capacitor structure of FIG. 5A. In FIG. 5D, some components in FIG. 5A are omitted to clearly illustrate the configuration of the opening OP2 and the opening OP3. FIG. 6A and FIG. 6B are top views illustrating conductive layers and connection terminals according to other embodiments of the invention. FIG. 6C is a top view illustrating a capacitor structure according to other embodiments of the invention. FIG. 5A, FIG. 5C, and FIG. 5D are cross-sectional views taken along section line III-III′ in FIG. 6C. FIG. 5B is a cross-sectional view taken along section line IV-IV′ in FIG. 6C. FIG. 7A and FIG. 7B are top views illustrating conductive layers and connection terminals according to other embodiments of the invention. FIG. 7C is a top view illustrating a capacitor structure according to other embodiments of the invention. FIG. 8A and FIG. 8B are top views illustrating conductive layers and connection terminals according to other embodiments of the invention. FIG. 8C is a top view illustrating a capacitor structure according to other embodiments of the invention. In the top view of the above embodiments, some components in the cross-sectional view are omitted to clearly illustrate the configuration relationship between the components in the top view.

Referring to FIG. 1A, FIG. 1B, FIG. 1C, FIG. 1D, FIG. 2A, FIG. 2B, FIG. 2C, FIG. 5A, FIG. 5B, FIG. 5C, FIG. 5D, FIG. 6A, FIG. 6B, and FIG. 6C, the difference between the capacitor structure 20 and the capacitor structure 10 is as follows. The capacitor structure 20 may include a plurality of the electrode layers 112 (e.g., electrode layer 112A and electrode layer 112B). In the capacitor structure 20, the number of the electrode layers 110 is, for example, two, the number of the electrode layers 112 is, for example, two, and the number of the dielectric layers 114 is, for example, three, but the invention is not limited thereto. As long as the number of the electrode layers 110 is at least two, the number of the electrode layers 112 is at least one, and the number of the dielectric layers 114 is at least two, it falls within the scope of the invention.

In the capacitor structure 20, there may be openings OP1 (e.g., opening OP11, opening OP12, and opening OP13) in the capacitor 102. In some embodiments, the opening OP11 may be located in the dielectric layer 114A, the electrode layer 112A, the dielectric layer 114B, the electrode layer 110B, the dielectric layer 114C, and the electrode layer 112B. In some embodiments, the opening OP11 may expose the top surface of the electrode layer 110A, the sidewall of the dielectric layer 114A, the top surface of the dielectric layer 114A, the sidewall of the electrode layer 112A, the sidewall of the dielectric layer 114B, the top surface of the dielectric layer 114B, the sidewall of the electrode layer 110B, the sidewall of the dielectric layer 114C, the top surface of the dielectric layer 114C, and the sidewall of the electrode layer 112B. In some embodiments, the cross-sectional shape of the opening OP11 may include a stepped shape, but the invention is not limited thereto.

In some embodiments, the opening OP 12 may be located in the dielectric layer 114B, the electrode layer 110B, the dielectric layer 114C, and the electrode layer 112B. In some embodiments, the opening OP12 may expose the top surface of the electrode layer 112A, the sidewall of the dielectric layer 114B, the top surface of the dielectric layer 114B, the sidewall of the electrode layer 110B, the sidewall of the dielectric layer 114C, the top surface of the dielectric layer 114C, and the sidewall of the electrode layer 112B. In some embodiments, the cross-sectional shape of the opening OP12 may include a stepped shape, but the invention is not limited thereto.

In some embodiments, the opening OP 13 may be located in the dielectric layer 114C and the electrode layer 112B. In some embodiments, the opening OP13 may expose the top surface of the electrode layer 110B, the sidewall of the dielectric layer 114C, the top surface of the dielectric layer 114C, and the sidewall of the electrode layer 112B. In some embodiments, the cross-sectional shape of the opening OP13 may include a stepped shape, but the invention is not limited thereto.

In the capacitor structure 20, the dielectric layer 104 may include a plurality of the openings OP3 (e.g., opening OP31 and opening OP32). In the capacitor structure 20, the openings OP3 may expose the electrode layers 112. That is, the opening OP3 may pass through the dielectric layer 104 to extend to the top surface of the electrode layer 112. In the capacitor structure 20, each of the openings OP3 exposes the corresponding electrode layer 112. In the capacitor structure 20, two adjacent openings OP3 may expose different electrode layers 112. For example, the opening OP31 may expose the electrode layer 112A, and the opening OP32 may expose the electrode layer 112B. In the capacitor structure 20, a portion of the openings OP3 may expose the same electrode layer 112. For example, as shown in FIG. 6C, the openings OP31 may expose the same electrode layer 112A. For example, as shown in FIG. 6C, the openings OP32 may expose the same electrode layer 112B. In the capacitor structure 20, the sidewall of the opening OP3 may be an inclined surface.

In the capacitor structure 20, the conductive layer 108 is electrically connected to the electrode layers 112. In the capacitor structure 20, the conductive layer 108 may be a single conductive layer disposed on the dielectric layer 104 and extending into the openings OP3. In this way, the electrode layers 112 can be electrically connected to each other by the conductive layer 108, thereby effectively reducing the process complexity and the manufacturing cost. In the capacitor structure 20, the conductive layer 108 may extend into all the openings OP3. That is, the conductive layer 108 may extend into all the openings OP31 and all the openings OP32. In some embodiments, the conductive layer 108 may be integrally formed.

In the capacitor structure 20, the conductive layer 108 may include a conductive line portion L2 and contact portions C2 (e.g., contact portion C21 and contact portion C22). The contact portions C2 are connected to the conductive line portion L2. In the capacitor structure 20, the conductive line portion L2 and the contact portions C2 may be integrally formed. Each of the contact portions C2 may be disposed in the corresponding opening OP3. In some embodiments, the contact portion C21 may be disposed in the corresponding opening OP31, and the contact portion C22 may be disposed in the corresponding opening OP32. In the present embodiment, as shown in FIG. 6B and FIG. 6C, the number of the contact portions C21 is, for example, plural, and the number of the contact portions C22 is, for example, plural, but the invention is not limited thereto. As long as the number of the contact portions C21 is at least one, and the number of the contact portions C22 is at least one, it falls within the scope of the invention. In addition, when the number of the contact portions C21 is plural, the equivalent series resistance can be effectively reduced. Furthermore, when the number of the contact portions C22 is plural, the equivalent series resistance can be effectively reduced. In some embodiments, as shown in FIG. 6B and FIG. 6C, the contact portions C21 and the contact portions C22 may be alternately arranged.

In addition, the top-view pattern of the conductive layer 106 is not limited to the top-view pattern as shown in FIG. 6A and FIG. 6C. In other embodiments, the top-view pattern of the conductive layer 106 may be the top-view pattern as shown in FIG. 7A, FIG. 7C, FIG. 8A, or FIG. 8C, and the description thereof is omitted here. Furthermore, the top-view pattern of the conductive layer 108 is not limited to the top-view pattern as shown in FIG. 6B and FIG. 6C. In other embodiments, the top-view pattern of the conductive layer 108 may be the top-view pattern as shown in FIG. 7B, FIG. 7C, FIG. 8B, or FIG. 8C, and the description thereof is omitted here.

Moreover, in the capacitor structure 10 and the capacitor structure 20, the same or similar components are denoted by the same reference symbols, and the description thereof is omitted.

Based on the above embodiments, in the capacitor structure 20, the capacitor 102 includes the electrode layers 110, the at least one electrode layer 112, and the dielectric layer 114. The electrode layers 110 and the at least one electrode layer 112 are alternately disposed on the substrate 100. The dielectric layer 114 is disposed between the electrode layer 110 and the electrode layer 112. The dielectric layer 104 has the openings OP2 exposing the electrode layers 110. The conductive layer 106 is electrically connected to the electrode layers 110. The conductive layer 106 is a single conductive layer disposed on the dielectric layer 104 and extending into the openings OP2. In this way, the electrode layers 110 can be electrically connected to each other by the conductive layer 106, thereby effectively reducing the process complexity and the manufacturing cost.

In summary, in the capacitor structure of the aforementioned embodiments, a capacitor includes first electrode layers, at least one second electrode layer, and a first dielectric layer. The first electrode layers and the at least one second electrode layer are alternately disposed on a substrate. The first dielectric layer is disposed between the first electrode layer and the second electrode layer. A second dielectric layer has first openings exposing the first electrode layers. A first conductive layer is electrically connected to the first electrode layers. The first conductive layer is a single conductive layer disposed on the second dielectric layer and extending into the first openings. In this way, the first electrode layers can be electrically connected to each other by the first conductive layer, thereby effectively reducing the process complexity and the manufacturing cost.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A capacitor structure, comprising:
a substrate;
a capacitor comprising:
first electrode layers and at least one second electrode layer alternately disposed on the substrate; and
a first dielectric layer disposed between one of the first electrode layers and the at least one second electrode layer;
a second dielectric layer disposed on the first electrode layers and the at least one second electrode layer and having first openings and at least one second opening, wherein the first openings expose the first electrode layers, and the at least one second opening exposes the at least one second electrode layer;
a first conductive layer electrically connected to the first electrode layers, wherein the first conductive layer is a single conductive layer disposed on the second dielectric layer and extending into the first openings; and
a second conductive layer electrically connected to the at least one second electrode layer and disposed on the second dielectric layer and in the at least one second opening.

2. The capacitor structure according to claim 1, wherein the first conductive layer extends into all the first openings.

3. The capacitor structure according to claim 1, wherein the first conductive layer comprises:
a conductive line portion; and
contact portions connected to the conductive line portion, wherein each of the contact portions is disposed in the corresponding first opening.

4. The capacitor structure according to claim 3, wherein the conductive line portion and the contact portions are integrally formed.

5. The capacitor structure according to claim 1, wherein a portion of the first openings exposes the same first electrode layer.

6. The capacitor structure according to claim 1, wherein two adjacent first openings expose different first electrode layers.

7. The capacitor structure according to claim 1, comprising a plurality of the second electrode layers, wherein the second dielectric layer comprises a plurality of the second openings, the second openings expose the second electrode layers, and the second conductive layer is a single conductive layer disposed on the second dielectric layer and extending into the second openings.

8. The capacitor structure according to claim 7, wherein the second conductive layer extends into all the second openings.

9. The capacitor structure according to claim 7, wherein a portion of the second openings exposes the same second electrode layer.

10. The capacitor structure according to claim 7, wherein two adjacent second openings expose different second electrode layers.

11. The capacitor structure according to claim 1, wherein the second conductive layer comprises:
conductive line portion; and
at least one contact portion connected to the conductive line portion, wherein the at least one contact portion is disposed in the at least one second opening.

12. The capacitor structure according to claim 11, wherein the conductive line portion and the at least one contact portion are integrally formed.

13. The capacitor structure according to claim 1, wherein a top surface of the first conductive layer and a top surface of the second conductive layer have the same height.

14. The capacitor structure according to claim 1, wherein there are third openings in the capacitor.

15. The capacitor structure according to claim 14, wherein a portion of the second dielectric layer is disposed in the third openings.

16. The capacitor structure according to claim 1, wherein a top-view pattern of the first conductive layer and a top-view pattern of the second conductive layer match each other.

17. The capacitor structure according to claim 1, wherein
a top-view pattern of the first conductive layer comprises a first comb-shaped portion,
a top-view pattern of the second conductive layer comprises a second comb-shaped portion, and
the first comb-shaped portion and the second comb-shaped portion match each other.

18. The capacitor structure according to claim 1, further comprising:
a first connection terminal electrically connected to the first electrode layers by the first conductive layer; and
a second connection terminal electrically connected to the at least one second electrode layer by the second conductive layer.

19. The capacitor structure according to claim 18, wherein
a top-view pattern of the first connection terminal comprises a first side, a second side, a third side, and a fourth side,
the first side and the third side are opposite to each other,
the second side and the fourth side are opposite to each other,
the second side is connected to the first side and the third side and is disposed between the first side and the third side,
the fourth side is connected to the first side and the third side and is disposed between the first side and the third side,
a top-view pattern of the second connection terminal comprises a fifth side, a sixth side, a seventh side, and an eighth side,
the fifth side and the seventh side are opposite to each other,
the sixth side and the eighth side are opposite to each other,
the sixth side is connected to the fifth side and the seventh side and is disposed between the fifth side and the seventh side, and
the eighth side is connected to the fifth side and the seventh side and is disposed between the fifth side and the seventh side.

20. The capacitor structure according to claim 19, wherein
a top-view pattern of the first conductive layer comprises:
a first main portion disposed directly below the top-view pattern of the first connection terminal;
a first extension portion connected to the first main portion, wherein the first extension portion is disposed between the top-view pattern of the first connection terminal and the top-view pattern of the second connection terminal and is adjacent to the fifth side of the second connection terminal; and
a second extension portion connected to the first main portion, wherein the second extension portion surrounds the sixth side, the seventh side, and the eighth side of the second connection terminal, and
a top-view pattern of the second conductive layer comprises:
a second main portion disposed directly below the top-view pattern of the second connection terminal,
a third extension portion connected to the second main portion, wherein the third extension portion is disposed between the top-view pattern of the first connection terminal and the top-view pattern of the second connection terminal and is adjacent to the first side of the first connection terminal; and
a fourth extension portion connected to the second main portion, wherein the fourth extension portion surrounds the second side, the third side, and the fourth side of the first connection terminal.
